(19) United States
(12) Patent Application Publication
(10) Pub. No.: US 2007/0004116 A1
(43) Pub. Date: Jan. 4, 2007

(54) Trenched MOSFET termination with tungsten plug structures

(75) Inventor: Fwu-Iuan Hshieh, Saratoga, CA (US)

Correspondence Address: Bo-In Lin, 13445 Mandoli Drive, Los Altos Hills, CA, 94022, US

(73) Assignee: M-MOS Semiconductor Sdn. Bhd.

(21) Appl. No.: 11/332,593

(22) Filed: Jan. 12, 2006

Related U.S. Application Data
(63) Continuation-in-part of application No. 11/147,075, filed on Jun. 6, 2005.

(51) Int. Cl. H01L 21/8234; H01L 21/3205

(52) U.S. Cl. 438/197; 438/589

(57) ABSTRACT

A metal oxide semiconductor field effect transistor (MOSFET) device includes a termination area. The termination area has a trenched gate runner electrically connected to a trenched gate of said MOSFET. The MOSFET further includes a gate runner contact trench opened through an insulation layer covering the gate runner and into a gate dielectric filling in the trenched gate runner and the gate runner contact trench filled with a gate runner contact plug. The gate runner contact plug further includes a tungsten contact plug. The gate runner contact plug further includes a tungsten contact plug surrounded by a TiN/Ti barrier layer. The gate runner has a width narrower than one micrometer. The MOSFET further includes a field plate in electric contact with the gate runner contact plug. The gate dielectric filling in the trenched gate runner includes a gate polysilicon filling in the trenched gate runner in the termination area. The gate runner contact plug has a bottom portion extends through the insulation layer into the gate dielectric whereby contact areas are increased with the contact plug contacting the gate dielectric to reduce a gate contact resistance.

This Patent application is a Continuation in Part (CIP) Application of a co-pending application Ser. No. 11/147,075 filed by a common Inventor of this Application on Jun. 6, 2005 with a Serial Number. The Disclosures made in that Application is hereby incorporated by reference.

### BACKGROUND OF THE INVENTION

1. Field of the Invention

This invention relates generally to the cell structure, device configuration and fabrication process of power semiconductor devices. More particularly, this invention relates to a novel and improved termination configuration with gate runner of reduced width and improved trenched gate runner contact formed with tungsten plugs wherein the termination areas may be further reduced with floating rings formed in the substrate to replace the functions of a field plate.

2. Description of the Related Art

Conventional semiconductor power devices are still limited by a technical difficulty in further increasing the cell density on a limited wafer surface area due to the space occupied by the termination area. Specifically, the conventional semiconductor power devices generally place a gate runner in the termination area by providing a wide trench. The greater width of the gate runner trench is required to allow gate metal contact directly to gate poly in the trench without causing gate and source shortage. A wider gate-runner trench in the termination area introduces another manufacturing difficulty due to a process requirement that a thicker polysilicon layer is applied to fill in the wider gate runner trench. Moreover, a thicker layer of polysilicon layer requires more elaborated and time consuming processes of processing chemical and mechanical planarization (CMP) or a longer dry polysilicon etch to obtain a more even-leveled and smooth planar top surface for better metal step coverage. The conventional termination configuration of the semiconductor power devices thus leads to more costly and time consuming manufacturing processes due to the wider gate-runner trenches generally implemented in a metal oxide semiconductor field effect transistor (MOSFET).

Referring to FIG. 1 for a standard conventional MOSFET cell 10 formed in a semiconductor substrate 15 with a drain region of a first conductivity type, e.g., an N+ substrate, formed at a bottom surface. The trenched MOSFET cell is formed on top of an epitaxial layer 20 of a first conductivity type, e.g., N-epi-layer that having a lower dopant concentration than the substrate. A body region 25 of a second conductivity type, e.g., a P-body region 25, is formed in the epi-layer 20 and the body region 25 encompasses a source region 30 of the first conductivity type, e.g., N+ source region 30. Each MOSFET cell further includes a N+ doped polysilicon gate 35 disposed in a trench insulated from the surrounding epi-layer 20 with a gate oxide layer 40. The MOSFET cell is insulated from the top by an NSG and BPSG layer 45 with a source contact opening 50 to allow a source contact metal layer 60 comprises Ti/TiN/AlCu or Ti/TiN/AlSiCu layer to contact the source regions 30. The single metal contact layer 60 overlaying on top to contact the N+ and P-well horizontally. In the termination area of the MOSFET device 10 a wide gate runner trench 35′ is opened. Above the wide gate runner 35′ in the termination area, a gate runner contact 50′ is formed in the insulation layer 45. The gate runner contact 50′ is in electric contact with a planar field plate 70 and a gate pad (not shown). Both the planar field plate 70 and the wide trenched gate runner 35′, occupy a greater space and limit the further increase of the cell density of the power semiconductor device.

There is an urgent need to reduce the width of the metal gate-runner and gate runner contact structure as the cell density of the semiconductor power devices increases. Specifically, several critical dimensions (CDs) including the distance between the contact and the trench in both the active and the termination areas becomes a limiting factor. As mentioned above, a single metal contact to trench gate poly encounters a cost effective issue due to a thicker poly deposition and longer poly etch back for good gate metal contact to trench poly. Furthermore, conventional device implements a long gate metal runner as planar metal field plate to relax the electrical field of P-body/N-epi in the termination area for sustaining a higher avalanche voltage. However, The length of metal gate runner must be 10˜20 μm longer than the width of the P-body in the termination region for avalanche voltage raging from 20˜40V. Thus the length of the field plate implemented as a gate runner in the termination area becomes a limiting factor preventing further reduction of device area while increase of the cell density in manufacturing the semiconductor power devices to shrink die size.

Therefore, there is still a need in the art of the semiconductor device fabrication, particularly for trenched power MOSFET design and fabrication, particularly in the termination area, to provide a novel cell structure, device configuration and fabrication process that would resolve these difficulties and design limitations. Specifically, it is desirable to maintain good electric contact to the trenched gate runner, to reduce the space occupied by the gate runner and to simplify the planarization process with gate runner of reduced width such that the above discussed difficulties and limitations may be resolved.

### SUMMARY OF THE PRESENT INVENTION

It is therefore an object of the present invention to provide new and improved semiconductor power device configuration with reduced width of metal gate-runner as metal field plate in the termination area. Metal step coverage of gate runner is also improved by opening a gate runner contact trench through an insulation layer and by filling the contact trench with a trenched gate runner contact plug. The trenched gate runner plug is composed of tungsten to establish reliable and good electric contact with the gate runner.

Briefly, in a preferred embodiment, the present invention discloses metal oxide semiconductor field effect transistor (MOSFET) device includes a termination area that has a trenched gate runner electrically connected to a trenched gate of said MOSFET. The MOSFET further includes a gate runner contact trench opened through an insulation layer covering the gate runner and into a gate dielectric filling in the trenched gate runner and the gate runner contact trench filled with a gate runner contact plug. The gate runner contact plug further includes a tungsten contact plug. The gate runner contact plug further includes a tungsten contact plug surrounded by a TiN/Ti barrier layer. The gate runner has a width narrower than one micrometer. The MOSFET further includes a field plate in electric contact with the gate runner contact plug. The gate dielectric filling in the trenched gate runner includes a gate polysilicon filling in the trenched gate runner in the termination area. The gate runner contact plug has a bottom portion extends through the insulation layer into the gate dielectric whereby contact areas are increased with the contact plug contacting the gate dielectric to reduce a gate contact resistance. The MOSFET device further includes a high concentration source dopant region disposed below the trenched gate for reducing a drain to source resistance Rds. The MOSFET device further includes a high concentration source dopant region disposed in the termination area next to a body dopant region in the termination area electrically connected to the body region for inducing an avalanche in a N-P junction interfacing between the high concentration source dopant region and the body dopant region in the termination area whereby a field plate is not required.

These and other objects and advantages of the present invention will no doubt become obvious to those of ordinary skill in the art after having read the following detailed description of the preferred embodiment, which is illustrated in the various drawing figures.

### BRIEF DESCRIPTION OF THE DRAWINGS

FIG. 1 is a side cross sectional view of a conventional MOSFET device with trenched gate runner with increased width and long planar plate in the termination area.

FIGS. 2A and 2B are respectfully a side cross sectional view and top view of a first embodiment for a MOSFET with an improved configuration in the termination area for the present invention.

FIGS. 3A and 3B are respectfully a side cross sectional view and top view of a second embodiment for a MOSFET with an improved configuration in the termination area for the present invention.

FIGS. 4A to 4D are a serial of side cross sectional views for showing the processing steps for fabricating a MOSFET device as shown in FIGS. 2A to 2B.

FIGS. 5A to 5D are a serial of side cross sectional views for showing the processing steps for fabricating a MOSFET device as shown in FIGS. 3A to 3B.

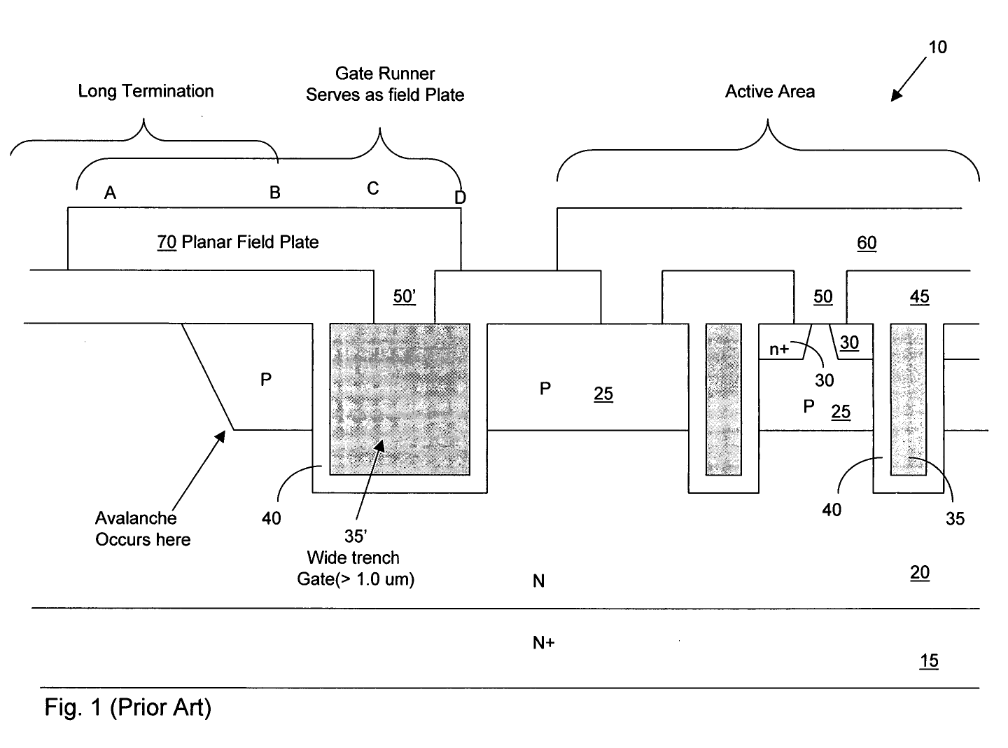

### DETAILED DESCRIPTION OF THE PREFERRED EMBODIMENT

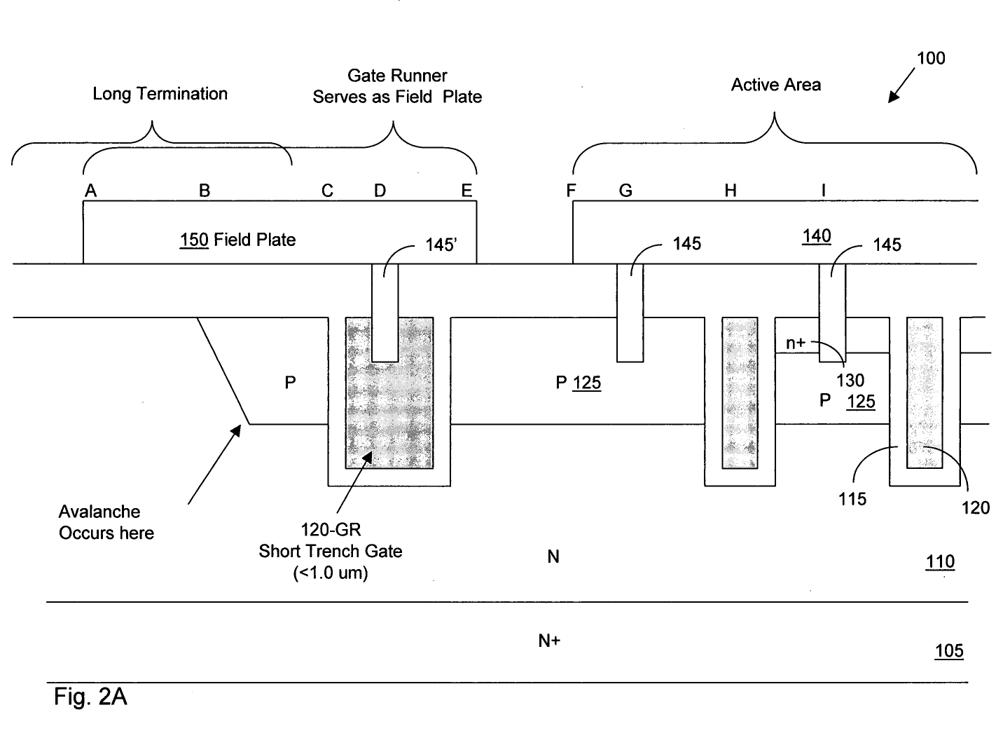

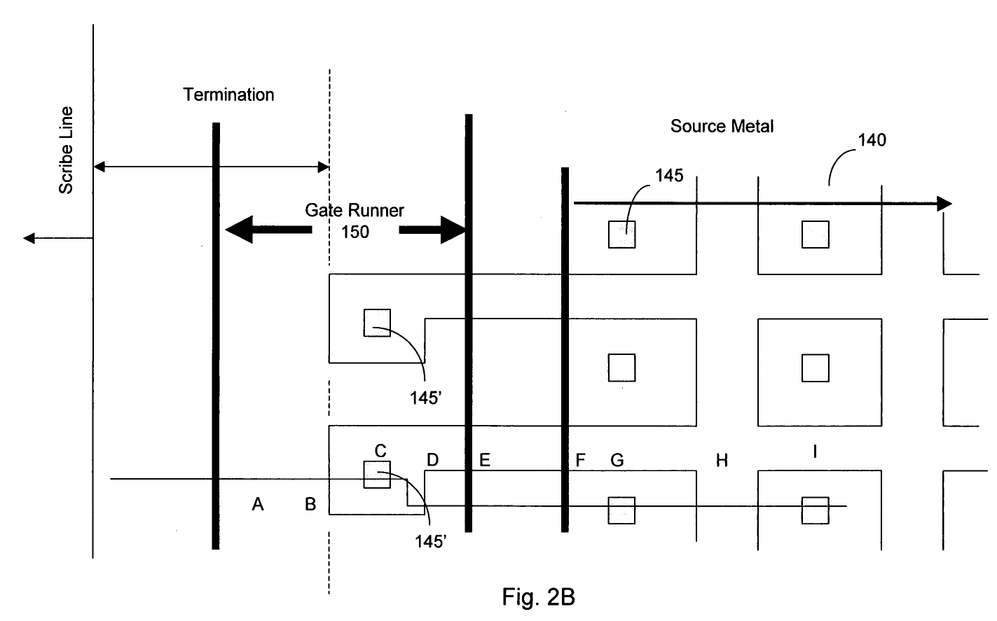

Please refer to FIGS. 2A to 2B for the side cross sectional view and top view of a first preferred embodiment of this invention where a metal oxide semiconductor field effect transistor (MOSFET) device 100 is supported on a substrate 105 formed with an epitaxial layer 110. The MOSFET device 100 includes a trenched gate 120 disposed in a trench with a gate insulation layer 115 formed over the walls of the trench. A body region 125 that is doped with a dopant of second conductivity type, e.g., P-type dopant, extends between the trenched gates 120. The P-body regions 125 encompassing a source region 130 doped with the dopant of first conductivity, e.g., N+ dopant. The source regions 130 are formed near the top surface of the epitaxial layer surrounding the trenched gates 120. The top surface of the semiconductor substrate extending over the top of the trenched gate, the P body regions 125 and the source regions 130 are covered with a NSG and a BPSG protective layers 135. A source metal layer 140 and gate metal layer (not shown) are formed on top of the protective insulation layer 135.

For the purpose of improving the source contact to the source regions 130, a plurality of trenched source contact filled with a tungsten plug 145 that is surrounded by a barrier layer Ti/TiN. The contact trenches are opened through the NSG and BPSG protective layers 135 to contact the source regions 130 and the P-body 125. Then a conductive layer with low resistance (not shown) is formed over the top surface to contact the trenched source contact 145. A top contact layer 140 is then formed on top of the source contact 145. The top contact layer 140 is formed with aluminum, aluminum-cooper, AlCuSi, or Ni/Ag, Al/NiAu, AlCu/NiAu or AlCuSi/NiAu as a wire-bonding layer. The low resistance conductive layer (not shown) sandwiched between the top wire-bonding layer 140 and the top of the trenched source-plug contact 145 is formed to reduce the resistance by providing greater area of electrical contact.

In order to further increase the active areas for ultra high cell density MOSFET device, a specially configured termination structure is disclosed in the present invention. The termination includes a planar field plate 150 formed on top of a shortened gate runner 120-GR that is shorter than one micrometer. In order to assure good contact to the gate runner 120-GR, a trenched gate runner contact plug 145′ is formed on top of the gate runner 120-GR. The gate-runner contact plug 145′ is composed of tungsten surrounded by a Ti/TiN barrier layer. By implementing a trenched gate-runner plug 145′, a good and reliable contact is established and meanwhile the width of the gate runner 120-GR is shortened. Savings of the mesa space is achieved in the active area. This is especially beneficial for the ultra-high density MOSFET device. Because of the shortened width of the gate runner 120-GR, the planarization process is simplified because there is only a thin polysilicon layer formed in filling up the shortened gate runner. The gate metal runner 150 now serves as the planar metal field plate that extends toward the termination area. The shortened gate runner 120-GR has improved electrical contact with tungsten plug for more cost effective and better metal step coverage.

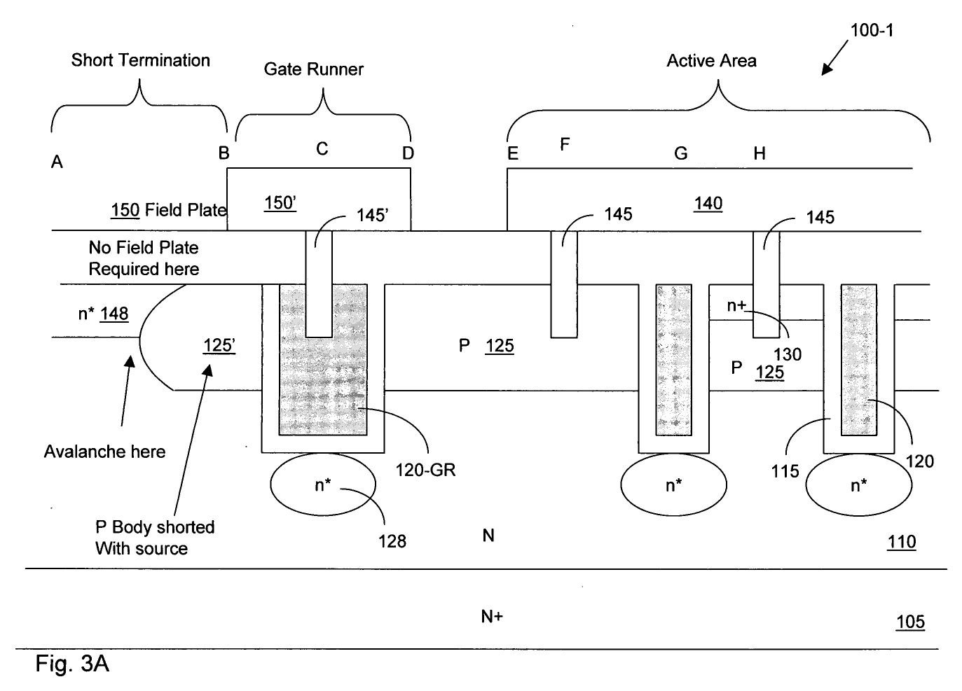

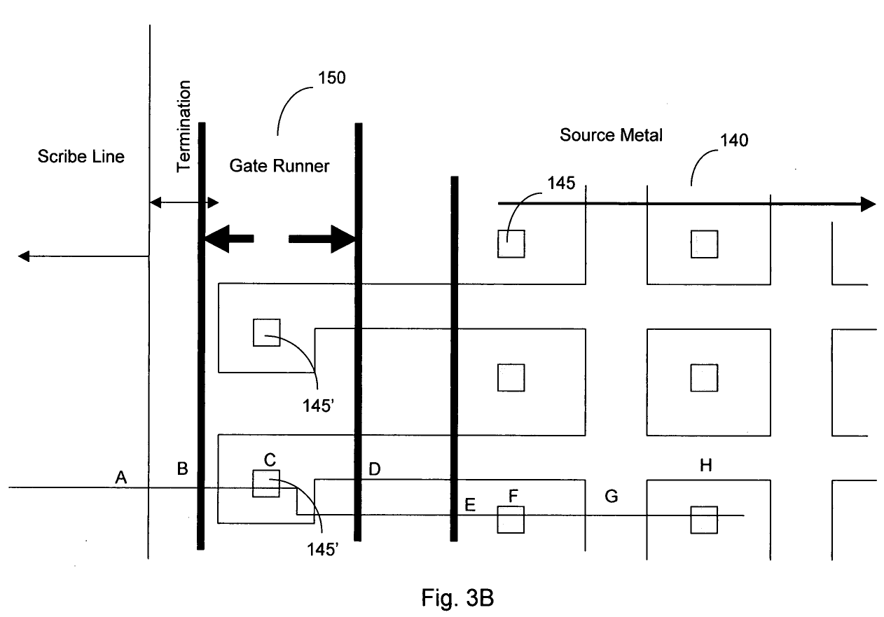

Referring to FIGS. 3A and 3B for a cross sectional view and a top view respectively for another MOSFET device 100-1 as an alternate embodiment of this invention. The MOSFET device 100-1 is similar in basic configuration and structure as that of MOSFET 100 shown in FIGS. 2A and 2B. There are additional N* doped regions 128 below the trenched gate 120 that are doped with As or phosphorous ions. The N* doped regions 128 below the trenched gates reduce the drain to source resistance (Rds). The N* doped regions 128 have a doping concentration higher than N epi layer 110. A Rds reduction of 15˜30% less darin-to-source resistance is achievable with the additional N* doped region underneath trench. Furthermore, in addition to the benefits of a shortened gate runner 150′ in contact with a trenched gate runner contact plug 145′; the space required for the termination area is further reduced. There is no field plate beyond the P-body 125′ in termination area required as result of avalanche occurrence at N*/P-body junction instead of Si/dielectric surface required by conventional metal field plate. The termination area is shortened. Additionally, an N* doped region 148 is formed in the termination area next to the p-body 125′. With the p-body 125′ now shorted to the source contact, an avalanche is induced in the N*-P junction area that is near the bottom of the p-body region 125′ in the termination area.

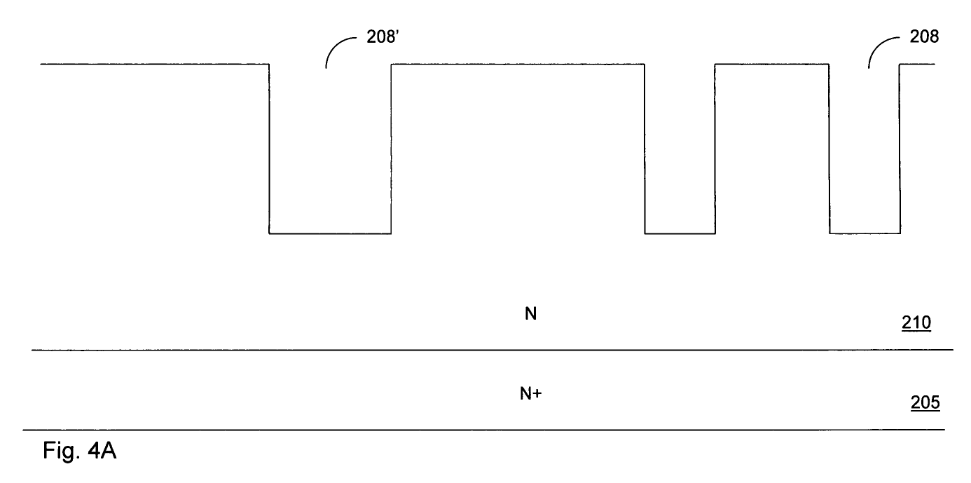

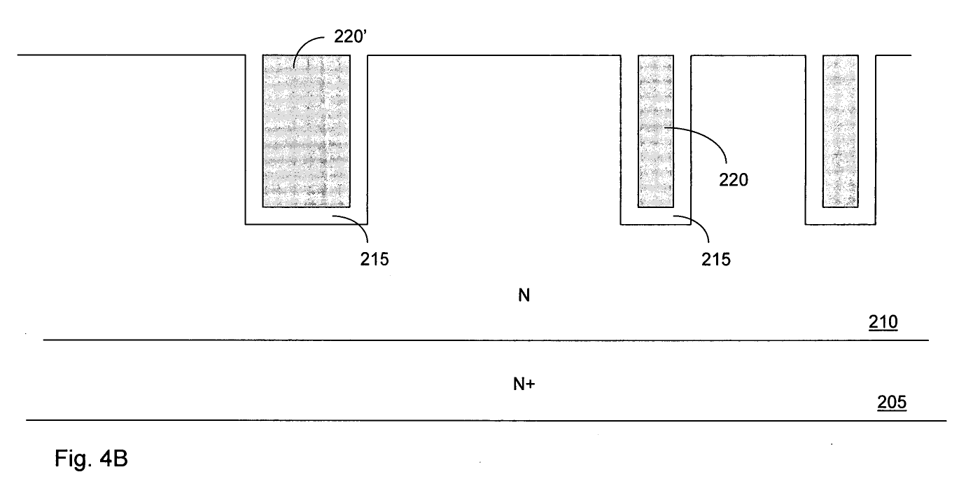

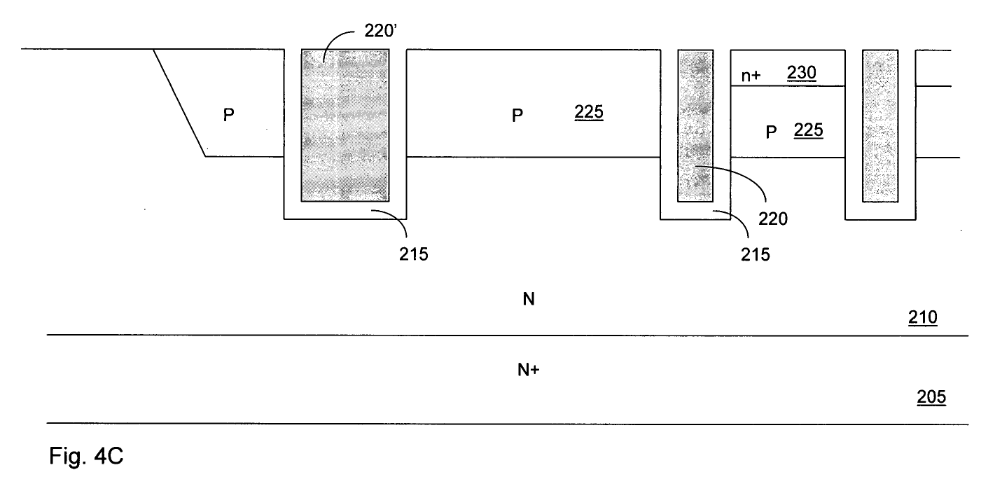

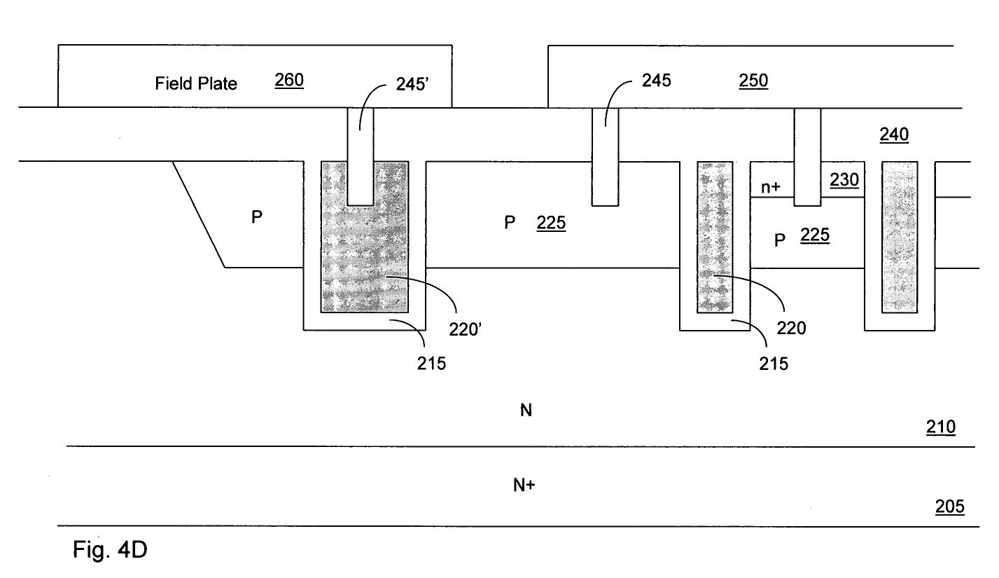

Referring to FIGS. 4A to 4D for a serial of side cross sectional views to illustrate the fabrication steps of a MOSFET device as that shown in FIGS. 2A to 2B. In FIG. 4A, a trench mask (not shown) is applied to open a plurality of trenches 208 in an epitaxial layer 210 supported on a substrate 205 by employing a dry silicon etch process. In the termination area, a wider trench 208's is also formed. In FIG. 4B, an oxidation process is performed to form an oxide layer covering the trench walls. The trench is oxidized with a sacrificial oxide to remove the plasma damaged silicon layer during the process of opening the trench. Then an oxide layer 215 is grown followed by depositing a polysilicon layer 220 to fill the trench and covering the top surface and then doped with an N+ dopant. The polysilicon layer 220 and 220′ filling the wider trench 208′ are either etched back or removed by applying a chemical mechanical planarization process (CMP) to remove the polysilicon above the top surface.

In FIG. 4C, the manufacturing process proceeds with a P-body implant with a P-type dopant. Then an elevated temperature is applied to diffuse the P-body 225 into the epitaxial layer 210. The processes continues with an application of a source mask (not shown) to carry out a N+ source implant into a plurality of source regions followed by driving in the source dopant by applying an elevated temperature to form the source regions 230. In FIG. 4D, a non-doped oxide (NSG) layer and a BPSG layer 240 are deposited on the top surface followed by applying a contact mask to carry out a contact etch to open the source-body contact trenches 245 by applying an oxide etch through the BPSG and NSG layers 240 followed by a silicon etch to open the contact openings further deeper into the source regions 230 and the body regions 225. In the termination area, a contact trench 245′ is also formed through the same processes with the trenched contact plug 245′ in electrical contact with the wide trenched gate runner 220′. The oxide etch and silicon etch may be a dry oxide and silicon etch whereby a critical dimension (CD) of the source-body contact trench is better controlled. The source-body contact trenches are then filled with a Ti/TiN/W layer 245 and 245′ in the termination area. A low resistance conductive layer (not shown) may be formed on top to cover the oxide layer 240 and also to contact the source body contact layer 245 and 245′ in the termination area to increase the current conduction areas to reduce the contact resistance. The low resistance metal layer deposited over the top surface may be composed of Ti or Ti/TiN to assure good electric contact is established. Then a top metal conductive layer composed of AlCu is deposited and followed by a metal etch to pattern the metal layer into a source metal pad 250 and field plate 260 in the termination area in electrical contact with the gate runner 220′ through the trenched gate runner contact plug 245′.

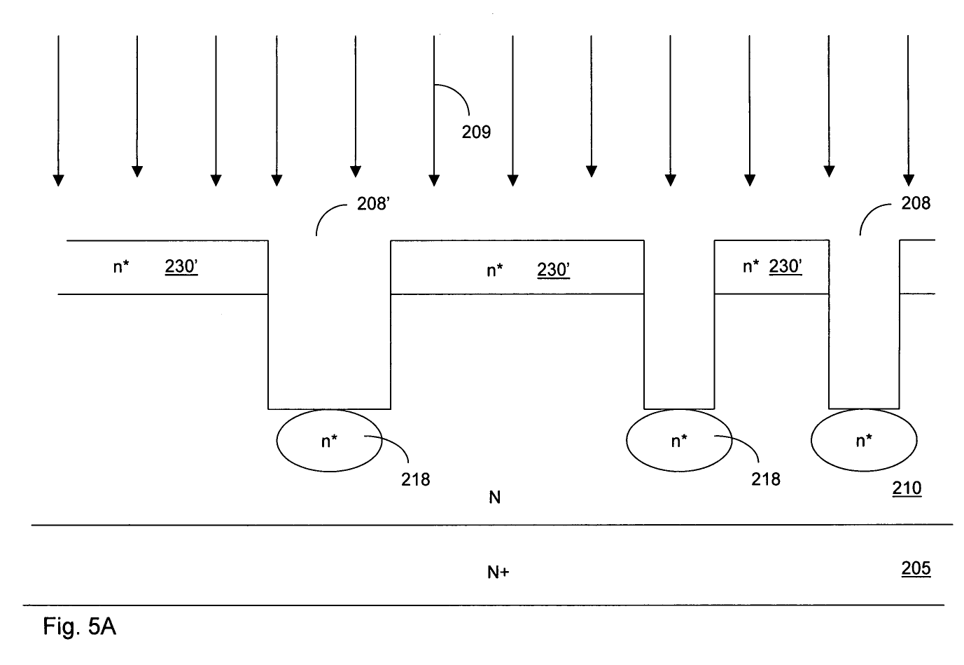

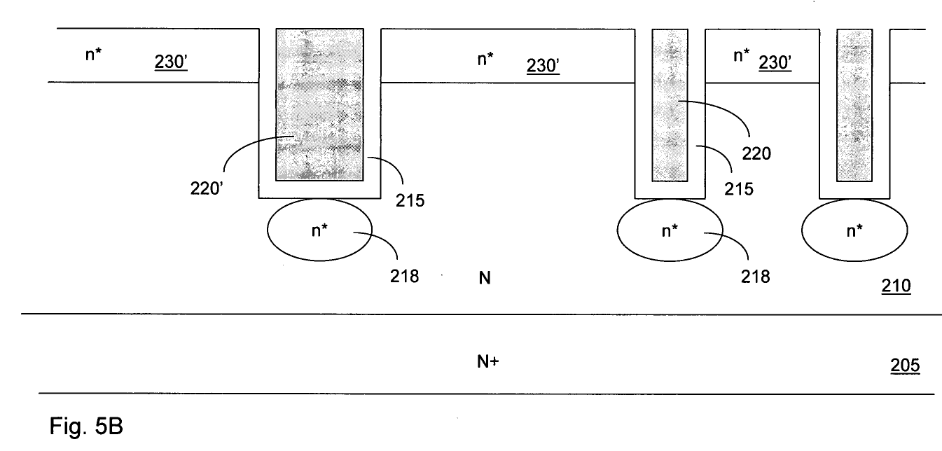

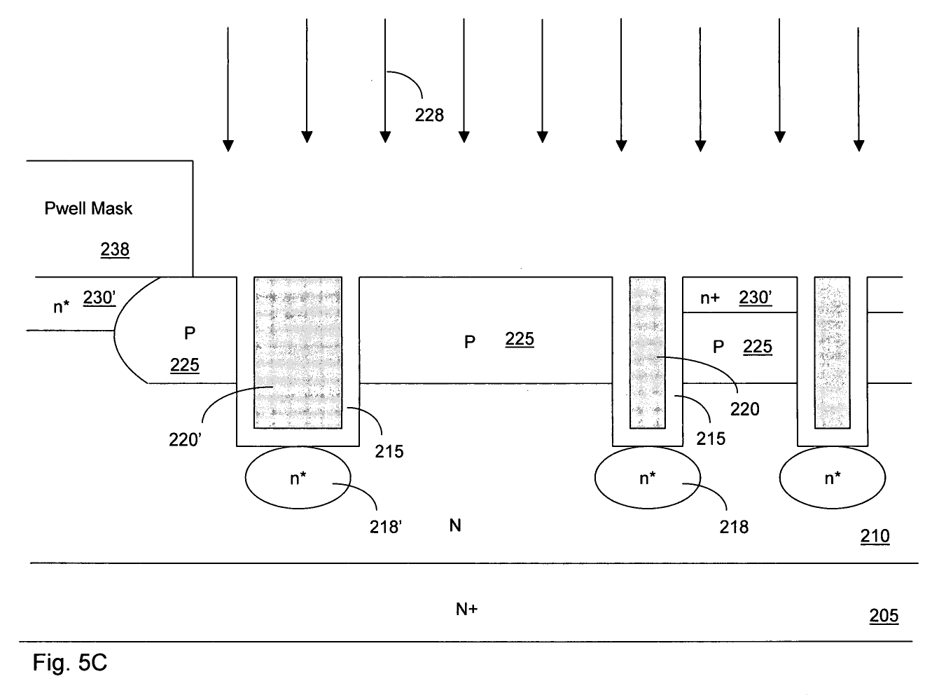

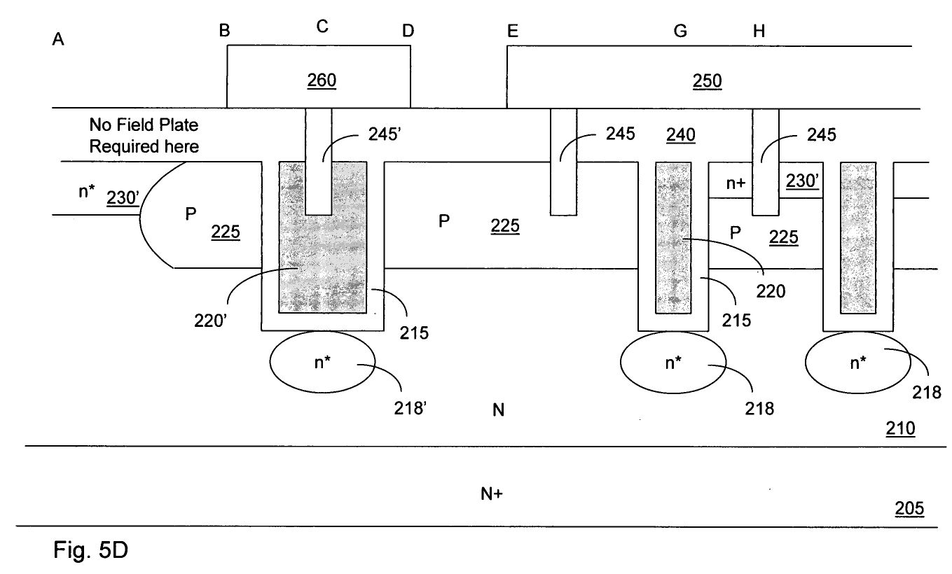

Referring to FIGS. 5A to 5D for a serial of side cross sectional views to illustrate the fabrication steps of a MOSFET device as that shown in FIGS. 3A to 3B. In FIG. 5A, a trench mask (not shown) is applied to open a plurality of trenches 208 in an epitaxial layer 210 supported on a substrate 205 by employing a dry silicon etch process. In the termination area, a wider trench 208's is also formed. An oxidation process is performed to form an oxide layer covering the trench walls. The trench is oxidized with a sacrificial oxide to remove the plasma damaged silicon layer during the process of opening the trenches. The processes of manufacturing proceed with an ion implantation with As ions 209 to form the buried gate-drain resistance (Rds) reduction regions 218 below the bottom of the trenches 208 and 208′. The As ion implantation also forms a high source dopant concentration regions 230′ near the top surface of the substrate surrounding the trenches 208 and 208′.

In FIG. 5B, an oxide layer 215 is grown followed by depositing a polysilicon layer 220 to fill the trench and covering the top surface and then doped with an N+ dopant. The polysilicon layer 220 and 220′ filling the wider trench 208′ are either etched back or removed by applying a chemical mechanical planarization process (CMP) to remove the polysilicon above the top surface. In FIG. 5C, the manufacturing process proceeds with a P-body implant with a P-type dopant ions 228 by applying a P-well mask 238. Then an elevated temperature is applied to diffuse the P-body 225 and the source region 230 into the epitaxial layer 210.

In FIG. 5D, a non-doped oxide (NSG) layer and a BPSG layer 240 are deposited on the top surface followed by applying a contact mask to carry out a contact etch to open the source-body contact trenches 245 by applying a oxide etch through the BPSG and NSG layers 240 followed by a dry silicon etch to open the contact openings further deeper into the source regions 230 and the body regions 225. In the termination area, a contact trench 245′ is also formed through the same processes. The oxide etch and silicon etch may be a dry oxide and silicon etch whereby a critical dimension (CD) of the source-body contact trench is better controlled. The source-body contact trenches are then filled with a Ti/TiN/W layer 245 and 245′ in the termination area. A low resistance conductive layer (not shown) may be formed on top to cover the oxide layer 240 and also to contact the source body contact layer 245 and 245′ in the termination area to increase the current conduction areas to reduce the contact resistance. The low resistance metal layer deposited over the top surface may be composed of Ti or Ti/TiN to assure good electric contact is established. Then a top metal conductive layer composed of AlCu is deposited and followed by a metal etch to pattern the metal layer into a source metal pad 250 and gate-runner plate 260 in the termination area in electrical contact with the gate runner 220′ through the trenched gate runner contact plug 245′.

According to above descriptions, this invention further discloses a method for manufacturing a metal oxide semiconductor field effect transistor (MOSFET) device with a termination area. The termination area is formed with a trenched gate runner electrically connected to a trenched gate of said MOSFET. The method further includes a step of opening a gate runner contact trench through an insulation layer covering the gate runner and into a gate dielectric filling in the trenched gate runner. The method further includes a step of filling the gate runner contact trench with a gate runner contact plug. In a preferred embodiment, the step of filling the gate runner contact trench with a gate runner contact plug further includes a step of filling the gate runner contact trench with a tungsten contact plug. In another preferred embodiment, the step of filling the gate runner contact trench with a gate runner contact plug further includes a step of filling the gate runner contact trench with a tungsten contact plug and surrounding the tungsten contact plug with a Ti/TiN barrier layer. In another preferred embodiment, the step of forming the trenched gate runner in the termination area further includes a step of forming the gate runner with a width narrower than one micrometer. In another preferred embodiment, the method further includes a step of forming and patterning a field plate in electric contact with the gate runner contact plug in the termination area. In a preferred embodiment, the step of filling the trenched gate runner with the gate dielectric includes a step of filling the trenched gate runner in the termination area with a gate polysilicon. In a preferred embodiment, the step of filling the trench gate runner with the gate runner contact plug further includes a step of filling the trenched gate runner with a bottom portion of the gate runner contact plug extending through the insulation layer into the gate dielectric whereby contact areas are increased with the contact plug contacting the gate dielectric to reduce a gate contact resistance. In a preferred embodiment, the method further includes a step of forming a high concentration source dopant region below the trenched gate for reducing a drain to source resistance Rds. In a preferred embodiment, the method further includes a step of forming a high concentration source dopant region in the termination area next to a body dopant region in the termination area electrically connected to the body region for inducing an avalanche in a N-P junction interfacing between the high concentration source dopant region and the body dopant region in the termination area whereby a field plate is not required. In a preferred embodiment, the method further includes a step of forming a high concentration source dopant region below the trenched gate and trenched gate runner for reducing a drain to source resistance Rds and a high concentration source dopant region in the termination area. And, the method further includes a step of applying a p-well mask in implanting p-body dopant ions to form a p-body dopant region next to and electrically connected to the high concentration source dopant region for inducing an avalanche in a N-P junction interfacing between the high concentration source dopant region and the body dopant region in the termination area whereby a field plate is not required.

This application further includes a five-mask manufacturing process for manufacturing a power semiconductor device. The method includes a step of applying a trench mask for opening a plurality of gate trenches and a gate runner trench in a termination area followed by processes for forming trenched gate and trenched gate runner then a body implant and diffusion to form body regions. The method further includes a step of applying a body implant mask to form body regions with a body ring region in the termination area and applying a source implant mask for forming source regions followed by forming an overlying insulation layer. The method further includes a applying a contact trench mask to form contact trenches through the overlying insulation layer for opening source contact trenches, gate contact trenches and a gate runner contact trench in the termination area followed by filling the contact trenches with contact trench plugs and depositing a metal layer on a top surface of the insulation layer. And, the method further includes a step of applying a metal mask for patterning the metal layer into a field plate above the body ring region in the termination area and a source metal in electrical contact with the gate runner contact plug and the source contact plugs respectively

Although the present invention has been described in terms of the presently preferred embodiment, it is to be understood that such disclosure is not to be interpreted as limiting. Various alternations and modifications will no doubt become apparent to those skilled in the art after reading the above disclosure. Accordingly, it is intended that the appended claims be interpreted as covering all alternations and modifications as fall within the true spirit and scope of the invention.

I claim:

1. A metal oxide semiconductor field effect transistor (MOSFET) device comprising a termination area including a trenched gate runner electrically connected to a trenched gate of said MOSFET, said MOSFET further comprising:
a gate runner contact trench opened through an insulation layer covering said gate runner and into a gate dielectric filling in said trenched gate runner and said gate runner contact trench filled with a gate runner contact plug.

2. The MOSFET device of claim 1 wherein:
said gate runner contact plug further comprising a tungsten contact plug.

3. The MOSFET device of claim 1 wherein:
said gate runner contact plug further comprising a tungsten contact plug surrounded by a TiN/Ti barrier layer.

4. The MOSFET device of claim 1 wherein:
said gate runner having a width narrower than one micrometer.

5. The MOSFET device of claim 1 further comprising:
a field plate in electric contact with said gate runner contact plug.

6. The MOSFET device of claim 1 wherein:
said gate dielectric filling in said trenched gate runner comprising a gate polysilicon filling in said trenched gate runner in said termination area.

7. The MOSFET device of claim 1 wherein:
said gate runner contact plug having a bottom portion extend through said insulation layer into said gate dielectric whereby contact areas are increased with said contact plug contacting said gate dielectric to reduce a gate contact resistance.

8. The MOSFET device of claim 1 further comprising:
a high concentration source dopant region disposed below said trenched gate for reducing a drain to source resistance Rds.

9. The MOSFET device of claim 1 further comprising:
a high concentration source dopant region disposed in said termination area next to a body dopant region in said termination area electrically connected to said body region for inducing an avalanche in a N-P junction interfacing between said high concentration source dopant region and said body dopant region in said termination area whereby a field plate is not required.

10. A method for manufacturing a metal oxide semiconductor field effect transistor (MOSFET) device with a termination area formed with a trenched gate runner electrically connected to a trenched gate of said MOSFET, said method further comprising:
opening a gate runner contact trench through an insulation layer covering said gate runner and into a gate dielectric filling in said trenched gate runner; and
filling said gate runner contact trench with a gate runner contact plug.

11. The method of claim 10 wherein:
said step of filling said gate runner contact trench with a gate runner contact plug further comprising a step of filling said gate runner contact trench with a tungsten contact plug.

12. The method of claim 10 wherein:
said step of filling said gate runner contact trench with a gate runner contact plug further comprising a step of filling said gate runner contact trench with a tungsten contact plug and surrounding said tungsten contact plug with a Ti/TiN barrier layer.

13. The method of claim 10 wherein:
said step of forming said trenched gate runner in said termination area further comprising a step of forming said gate runner with a width narrower than one micrometer.

14. The method of claim 10 further comprising:
forming and patterning a field plate in electric contact with said gate runner contact plug in said termination area.

15. The method of claim 10 wherein:
said step of filling said trenched gate runner with said gate dielectric comprising a step of filling said trenched gate runner in said termination area with a gate polysilicon.

16. The method of claim 10 wherein:
said step of filling said trench gate runner with said gate runner contact plug further comprising a step of filling said trenched gate runner with a bottom portion of said gate runner contact plug extending through said insulation layer into said gate dielectric whereby contact areas are increased with said contact plug contacting said gate dielectric to reduce a gate contact resistance.

17. The method of claim 10 further comprising:
forming a high concentration source dopant region below said trenched gate for reducing a drain to source resistance Rds.

18. The method of claim 10 further comprising:
forming a high concentration source dopant region in said termination area next to a body dopant region in said termination area electrically connected to said body region for inducing an avalanche in a N-P junction interfacing between said high concentration source dopant region and said body dopant region in said termination area whereby a field plate is not required.

19. The method of claim 10 further comprising:
forming a high concentration source dopant region below said trenched gate and trenched gate runner for reducing a drain to source resistance Rds and a high concentration source dopant region in said termination area; and
applying a p-well mask in implanting p-body dopant ions to form a p-body dopant region next to and electrically connected to said high concentration source dopant region for inducing an avalanche in a N-P junction interfacing between said high concentration source dopant region and said body dopant region in said termination area whereby a field plate is not required.

20. A five-mask manufacturing process for manufacturing a power semiconductor device comprising:
applying a trench mask for opening a plurality of gate trenches and a gate runner trench in a termination area followed by processes for forming trenched gate and trenched gate runner then a body implant and diffusion to form body regions;
applying a body implant mask to form body regions with a body ring region in said termination area and applying a source implant mask for forming source regions followed by forming an overlying insulation layer;
applying a contact trench mask to form contact trenches through said overlying insulation layer for opening source contact trenches, gate contact trenches and a gate runner contact trench in said termination area followed by filling said contact trenches with contact trench plugs and depositing a metal layer on a top surface of said insulation layer; and
applying a metal mask for patterning said metal layer into a field plate above said body ring region in said termination area and a source metal in electrical contact with said gate runner contact plug and said source contact plugs respectively.
